(19) United States
(12) Patent Application Publication
(10) Pub. No.: US 2025/0384930 A1
(43) Pub. Date: Dec. 18, 2025

(54) NON-VOLATILE MEMORY DEVICE AND METHOD FOR MANUFACTURING THE SAME

(71) Applicant: Samsung Electronics Co., Ltd., Suwon-si (KR)

(72) Inventor: DOO-HO CHO, Suwon-si (KR)

(21) Appl. No.: 19/095,326

(22) Filed: Mar. 31, 2025

(30) Foreign Application Priority Data
Jun. 18, 2024 (KR) 10-2024-0078999

(51) Int. Cl. G11C 16/08; G11C 5/06; H01L 21/66

(52) U.S. Cl. CPC G11C 16/08; G11C 5/063; H01L 22/34

(57) ABSTRACT

A non-volatile memory device including a memory cell array, a row decoder, a page buffer circuit, a control logic circuit, and a voltage generator includes at least one first die including the memory cell array including a plurality of blocks and the row decoder electrically connected to the memory cell array through a plurality of word lines, at least one second die including the page buffer circuit electrically connected to the memory cell array through a plurality of bit lines, and the control logic circuit configured to control an operation of the row decoder and the page buffer circuit, and a third die including the voltage generator configured to supply voltage to the row decoder and the page buffer circuit. The at least one first die, the at least one second die, and the third die are formed in a stacked structure.

### CROSS-REFERENCE TO RELATED APPLICATION

This application claims priority to Korean Patent Application No. 10-2024-0078999, filed in the Korean Intellectual Property Office on Jun. 18, 2024, the entire contents of which are hereby incorporated by reference.

### BACKGROUND

### Field

The present disclosure relates to a non-volatile memory device and a method for manufacturing the same.

### Description of Related Art

In recent years, the demand for memory devices for storing and processing data has increased rapidly, leading to diversified demands to tailor the memory devices to various application fields. For example, applications that require high-speed processing require a memory that provides fast read/write speeds, while applications that require massive data storage require a memory that can store a large amount of data at a low cost. In addition, power-efficient memory devices are essential in mobile devices or Internet of Things (IoT) devices where low power consumption is important.

Various types of memory devices are being developed to meet these various demands. Each memory device is designed and manufactured to provide optimized performance according to its characteristics. However, different manufacturing processes tailored to the characteristics of each memory device are required to manufacture various types of memory devices. These manufacturing processes require different process steps, equipment, or materials, which can lead to increased manufacturing costs.

The information described above is intended to improve understanding of the background of the present disclosure, and may include information that does not constitute the related art.

### SUMMARY

In order to solve one or more problems (e.g., the problems described above and/or other problems not explicitly described herein), the present disclosure relates to a non-volatile memory device and a method for manufacturing the same.

An object to be achieved by the present disclosure is not limited to the above, and other objects not mentioned may be clearly understood by those skilled in the art from the description of the present disclosure.

According to an aspect of the present disclosure, a non-volatile memory device including a memory cell array, a row decoder, a page buffer circuit, a control logic circuit, and a voltage generator includes at least one first die including the memory cell array including a plurality of blocks and the row decoder electrically connected to the memory cell array through a plurality of word lines, at least one second die including the page buffer circuit electrically connected to the memory cell array through a plurality of bit lines, and the control logic circuit configured to control an operation of the row decoder and the page buffer circuit, and a third die including the voltage generator configured to supply voltage to the row decoder and the page buffer circuit. The at least one first die, the at least one second die, and the third die are formed in a stacked structure.

According to an aspect of the present disclosure, a non-volatile memory device including a plurality of memory cell arrays, a plurality of row decoders, a plurality of page buffer circuits, a plurality of control logic circuits, a plurality of input and output circuits, and a voltage generator includes a plurality of first dies each including a corresponding memory cell array, among the plurality of memory cell arrays, including a plurality of blocks, and a corresponding row decoder, among the plurality of row decoders, electrically connected to the corresponding memory cell array through a plurality of word lines, a plurality of second dies each including a corresponding page buffer circuit, among the plurality of page buffer circuits, electrically connected to the corresponding memory cell array through a plurality of bit lines, a corresponding control logic circuit, among the plurality of control logic circuits, configured to control an operation of the corresponding row decoder and the corresponding page buffer circuit, and a corresponding input and output circuit, among the plurality of input and output circuits, electrically connected to the corresponding page buffer circuit and configured to transmit and receive data input to and read from the corresponding memory cell array, and a third die including the voltage generator configured to supply a voltage to the corresponding row decoder and the corresponding page buffer circuit. The plurality of first dies, the plurality of second dies, and the third die are formed in a stacked structure. The plurality of first dies further include a first die select circuit that receives an address and activates at least one of the plurality of first dies based on the address. The plurality of second dies further include a second die select circuit that receives the address and activates at least one of the plurality of second dies based on the address.

According to an aspect of the present disclosure, a method of manufacturing a non-volatile memory device including a memory cell array, a row decoder, a page buffer circuit, a control logic circuit, and a voltage generator includes manufacturing at least one first die including the memory cell array including a plurality of blocks, and the row decoder electrically connected to the memory cell array through a plurality of word lines, manufacturing at least one second die including the page buffer circuit and the control logic circuit, manufacturing a third die including the voltage generator, performing a test on each of the at least one first die, the at least one second die, and the third die, stacking the at least one first die, the at least one second die, and the third die to manufacture the non-volatile memory device, wherein in the non-volatile memory device, the page buffer circuit is electrically connected to the memory cell array through a plurality of bit lines, the control logic circuit is configured to control an operation of the row decoder and the page buffer circuit, and the voltage generator is configured to supply a voltage to the row decoder and the page buffer circuit, and performing a test on the non-volatile memory device.

According to various aspects of the present disclosure, it is possible to manufacture various types of memory devices by variously combining a plurality of dies included in the memory device.

According to various aspects of the present disclosure, it is possible to manufacture various types of memory devices by stacking a plurality of dies included in the memory device in various ways.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

FIG. 1 is a block diagram provided to explain a storage system.

FIG. 2 is a diagram illustrating an example of the non-volatile memory device.

FIG. 3 is a block diagram provided to explain an internal configuration of the non-volatile memory device.

FIG. 4 is a diagram provided to explain an internal configuration of the non-volatile memory device.

FIGS. 5 and 6 are diagrams provided to explain examples of non-volatile memory devices combined according to some aspects.

FIGS. 7 and 8 are diagrams provided to explain examples of non-volatile memory devices and stacked according to some aspects.

FIG. 9A is a diagram provided to explain a unique identifier generator.

FIG. 9B is a diagram provided to explain a unique identifier generator.

FIG. 10 is a diagram provided to explain the die select units.

FIG. 11 is a block diagram illustrating an example of the non-volatile memory device including the plurality of first dies.

FIG. 12 is a block diagram illustrating an example of the non-volatile memory device including the plurality of second dies.

FIG. 13 is a flowchart illustrating an example of a method for manufacturing a non-volatile memory device.

### DETAILED DESCRIPTION

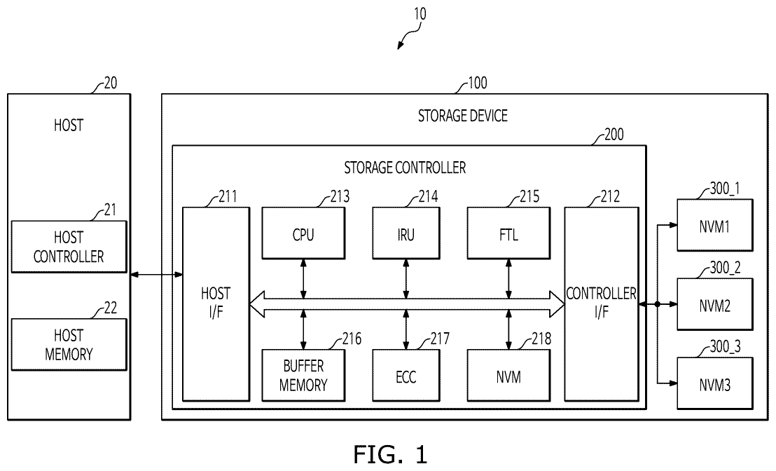

Hereinafter, various aspects of the present disclosure will be described with reference to FIGS. 1 to 13.

FIG. 1 is a block diagram provided to explain a storage system 10. Referring to FIG. 1, the storage system 10 may include a host 20 and a storage device 100. In addition, the storage device 100 may include a storage controller 200 and a plurality of non-volatile memory devices (NVM) 300_1 to 300_3. In addition, in some aspects, the host 20 may include a host controller 21 and a host memory 22. The host memory 22 may serve as a buffer memory for temporarily storing data to be transmitted to the storage device 100 or data transmitted from the storage device 100.

The storage device 100 may include a storage medium for storing data according to a request from the host 20. For example, the storage device 100 may include at least one of a solid state drive (SSD), an embedded memory, and a removable external memory. If the storage device 100 is an SSD, the storage device 100 may be a device conforming to the non-volatile memory express (NVMe) standard. If the storage device 100 is an embedded memory or external memory, the storage device 100 may be a device conforming the universal flash storage (UFS) standard or the embedded multi-media card (eMMC) standard. The host 20 and the storage device 100 may generate and transmit packets according to the standard protocol of an interface standard such as the NVMe standard, the UFS standard, and the eMMC standard.

If the non-volatile memory devices 300_1 to 300_3 include a flash memory, the flash memory may include a two-dimensional (2D) NAND memory array or a three-dimensional (3D) (or vertical, or bonding-vertical) VNAND memory array. As another example, the storage device 100 may include various other types of non-volatile memories and/or volatile memories. For example, the storage device 100 may include at least one of volatile or non-volatile memories such as static RAM (SRAM), dynamic RAM (DRAM), synchronous DRAM (SDRAM), read only memory (ROM), programmable ROM (PROM), electrically programmable ROM (EPROM), electrically erasable and programmable ROM (EEPROM), magnetic RAM (MRAM), spin-transfer torque MRAM, conductive bridging RAM (CBRAM), ferroelectric RAM (FeRAM), phase RAM (PRAM), and resistive RAM.

In some aspects, the host controller 21 and the host memory 22 may be implemented as separate semiconductor chips. Alternatively, in some aspects, the host controller 21 and host memory 22 may be integrated on the same semiconductor chip. For example, the host controller 21 may be any one of a plurality of modules provided in the application processor, and the application processor may be implemented as a System on Chip (SoC). In addition, the host memory 22 may be an embedded memory provided in the application processor, or may be a volatile memory or memory module disposed outside the application processor.

The host controller 21 may manage the operation of storing data (e.g., write data) of the host memory 22 in the non-volatile memory devices 300_1 to 300_3, or storing data (e.g., read data) of a non-volatile memory device 300 in the host memory 22. For example, the host controller 21 may manage the operation of storing user data associated with the execution of a specific program in the non-volatile memory devices 300_1 to 300 3.

The storage controller 200 may include a host interface 211, a controller interface 212, and a central processing unit (CPU) 213. In addition, the storage controller 200 may further include an index read unit (IRU) 214, a flash translation layer (FTL) 215, a buffer memory 216, an error correction code (ECC) 217, and an internal non-volatile memory 218. The storage controller 200 may further include a working memory in which the FTL 215 is loaded, and an operation of writing and reading data on the non-volatile memory may be controlled by the CPU 213 executing the FTL 215. For example, an operation of writing user data for the non-volatile memory devices 300_1 to 300_3 may be controlled by the CPU 213 executing the FTL 215.

The host interface 211 may transmit and receive packets to and from the host 20. The packet transmitted from the host 20 to the host interface 211 may include a command and/or data (e.g., user data) to be written to the non-volatile memory devices 300_1 to 300_3, and the packet transmitted from the host interface 211 to the host 20 may include a response to a command or data read from the non-volatile memory devices 300_1 to 300_3. The host interface 211 is illustrated as being included in the storage controller 200, but is not limited thereto. For example, the host interface 211 may be located outside the storage controller 200.

The controller interface 212 may transmit data (e.g., user data) to be written to the non-volatile memory devices 300_1 to 300_3 to the non-volatile memory devices 300_1 to 300_3, or may receive read data (e.g., user data) from the non-volatile memory devices 300_1 to 300_3. This controller interface 212 may be implemented to comply with standard protocols such as Toggle standard and the Open NAND Flash Interface (ONFI).

The flash translation layer 215 may perform several functions such as address mapping, wear-leveling, and garbage collection. In addition, the buffer memory 216 may temporarily store data to be written to the non-volatile memory devices 300 or data read from the non-volatile memory devices 300_1 to 300_3. The buffer memory 216 may be a component provided in the storage controller 200, but may be disposed outside the storage controller 200.

The ECC engine 217 may perform an error detection and correction function on read data read from the non-volatile memory devices 300_1 to 300_3. More specifically, the ECC engine 217 may generate a parity bit for write data to be written to the non-volatile memory devices 300_1 to 300_3, and the generated parity bit may be stored in the non-volatile memory devices 300_1 to 300_3 together with the write data. When reading data from the non-volatile memory devices 300_1 to 300_3, the ECC engine 217 may use the parity bit read from the non-volatile memory devices 300_1 to 300_3 together with the read data to correct errors in the read data, and output the error-corrected read data.

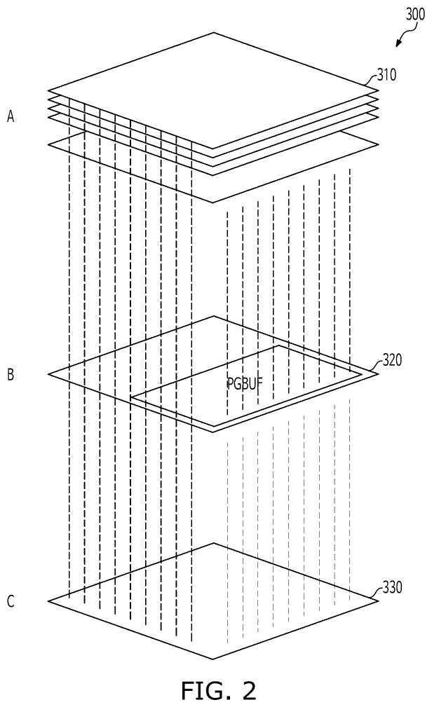

FIG. 2 is a diagram illustrating an example of the non-volatile memory device 300. Referring to FIG. 2, the non-volatile memory device 300 may include a first die 310, a second die 320, and a third die 330. In an embodiment, each of the non-volatile memory devices 300_1 to 300_3 of FIG. 1 may be implemented as the non-volatile memory device 300.

The first die 310 may include a memory cell array in which data is stored, and a row decoder electrically connected to the memory cell array through a plurality of word lines. The second die 320 may include a page buffer circuit electrically connected to the memory cell array through a plurality of bit lines, and a control logic circuit that controls operations of the row decoder and the page buffer circuit. In addition, the third die 330 may include a voltage generator that supplies a voltage to the row decoder and the page buffer circuit. In an embodiment, the non-volatile memory device 300 may include a memory cell array, a row decoder, a page buffer circuit, a control logic circuit, and a voltage generator which are distributed in the first to third dies 310 to 330. For example, the memory cell array and the row decoder may be disposed in the first die 310, the page buffer circuit and the control logic circuit may be disposed on the second die 320, and the voltage generator may be disposed in the third die 330.

The non-volatile memory device 300 may have a stacked structure in which the third die 330, the second die 320, and the first die 310 are sequentially stacked on each other. For example, as illustrated, the non-volatile memory device 300 may have a stacked structure in which the third die 330, the second die 320, and the first die 310 are sequentially stacked on each other from bottom to top, but aspects are not limited thereto. In another aspect, the non-volatile memory device 300 may have a stacked structure in which the first die 310, the second die 320, and the third die 330 are sequentially stacked on each other from bottom to top.

Each of the first die 310, the second die 320, and the third die 330 may be individually manufactured, and the non-volatile memory device 300 may be manufactured by stacking and bonding the first die 310, the second die 320, and the third die 330.

For example, a first wafer including the first die 310, a second wafer including the second die 320, and a third wafer including the third die 330 may be manufactured. The first wafer, the second wafer, and the third wafer may be stacked and bonded, and then diced to manufacture the non-volatile memory device 300 including the first die 310, the second die 320, and the third die 330.

As another example, the first wafer may be diced to manufacture the first die 310, the second wafer may be diced to manufacture the second die 320, and the third wafer may be diced to manufacture the third die 330. The first die 310, the second die 320, and the third die may be stacked and bonded to manufacture the non-volatile memory device 300.

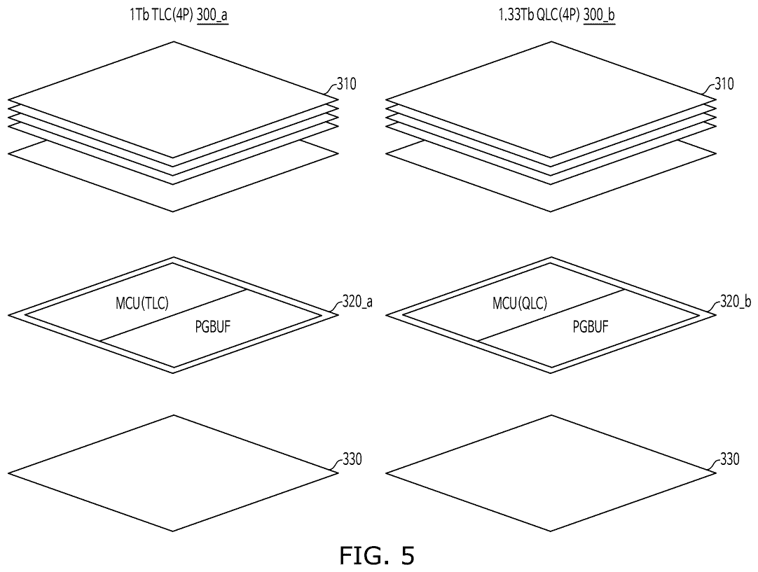

It is possible to manufacture various types of non-volatile memory devices 300 by combining and/or stacking the first die 310, the second die 320, and the third die 330 in various ways. This will be described in more detail below with reference to FIGS. 5 to 8.

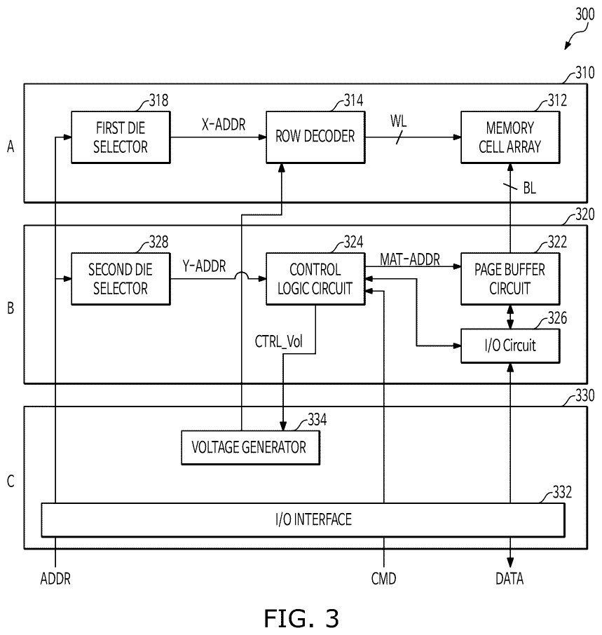

FIG. 3 is a block diagram provided to explain an internal configuration of the non-volatile memory device 300. Referring to FIG. 3, the non-volatile memory device 300 may include the first die 310, the second die 320, and the third die 330.

The first die 310 may include a memory cell array 312 and a row decoder 314. For example, the memory cell array 312 and the row decoder 314 may be disposed in the first die 310 among the first to third dies 310 to 330.

The memory cell array 312 may be electrically connected to the row decoder 314 through a plurality of word lines WL, and may be electrically connected to a page buffer circuit 322 included in the second die 320 through a plurality of bit lines BL. Additionally, the memory cell array 312 may be electrically connected to the row decoder 314 through a plurality of select lines (e.g., a string select line and a ground select line).

The memory cell array 312 may include a plurality of mats, and each of the mats may include a plurality of blocks. Each of the plurality of blocks may include a plurality of memory cells. The plurality of memory cells may be stacked on a substrate to form a three-dimensional structure. For example, the memory cell array 312 may include a plurality of cell strings disposed along row and column directions. Each of the plurality of memory cells may store one or more bits. The plurality of memory cells may be programmed, read, or erased by a voltage provided to the bit line BL and/or the word line WL.

The row decoder 314 may receive a row address X-ADDR and activate (or select) any one of the plurality of blocks of the memory cell array 312 based on the received row address X-ADDR. In addition, the row decoder 314 may activate the word line(s) of the activated block based on the row address X-ADDR and a control signal (not illustrated) received from a control logic circuit 324. For example, the row decoder 314 may transfer a word line voltage corresponding to the operation mode to the word lines of the activated block. For example, during the program operation, the row decoder 314 may apply a program voltage to the selected word line and apply a pass voltage to the unselected word line. As another example, during the read operation, the row decoder 314 may apply a read voltage to the selected word line and a read pass voltage to the unselected word line.

The first die 310 may further include a first die select unit 318 (i.e., a first die select circuit). The first die select unit 318 may receive an address ADDR from the outside (e.g., from the storage controller 200 of FIG. 1). The first die select unit 318 may select the row address X-ADDR from the received address ADDR and transfer the row address X-ADDR to the row decoder 314.

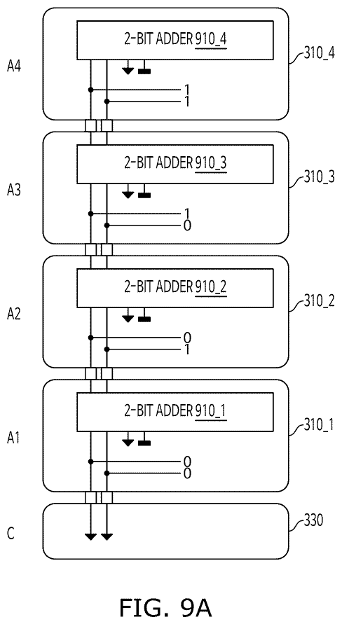

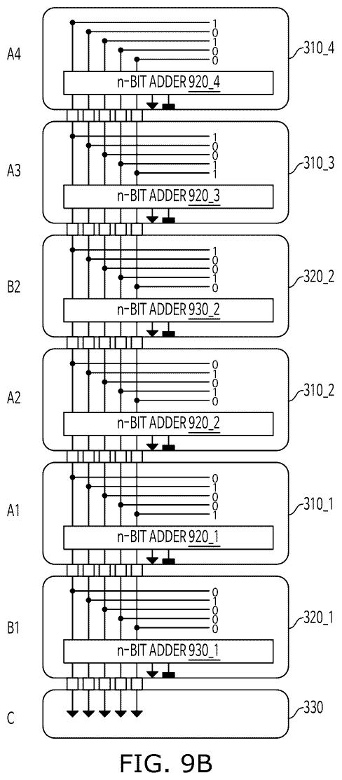

The first die 310 may be provided in plural. For example, a plurality of first dies 310 each of which has the configuration as shown in FIG. 3 are provided. The first die select unit 318 of each of the plurality of first dies 310 may activate a corresponding one of the plurality of first dies 310 based on the received address ADDR. This will be described in more detail below with reference to FIGS. 9A to 11.

The second die 320 may include the page buffer circuit 322 and the control logic circuit 324. For example, the page buffer circuit 322 and the control logic circuit 324 may be provided in the second die 320 among the first to third dies 310 to 330.

The page buffer circuit 322 may acquire a mat address MAT-ADDR. For example, the page buffer circuit 322 may receive the mat address MAT-ADDR from the control logic circuit 324. In an embodiment, the page buffer circuit 322 may receive a column address Y-ADDR from a second die select unit 328 (i.e., a second die select circuit). In this case, the page buffer circuit 322 may decode the received column address Y-ADDR to acquire the mat address MAT-ADDR. The page buffer circuit 322 may activate (i.e., select) at least some of the plurality of bit lines BL of the memory cell array 312 based on the mat address MAT-ADDR.

Depending on the operation mode, the page buffer circuit 322 may operate as a write driver or as a sense amplifier. For example, during the program operation, the page buffer circuit 322 may apply a bit line voltage corresponding to data to be programmed to at least some of the plurality of bit lines BL. As another example, during the read operation, the page buffer circuit 322 may sense data stored in a selected memory cell through the bit line BL. The page buffer circuit 322 may include a plurality of page buffers, and in this case, each of the plurality of page buffers may be electrically connected to at least one bit line.

The control logic circuit 324 may receive a command CMD and/or a column address Y-ADDR, and may control the overall operation of the non-volatile memory device 300 including the row decoder 314, the page buffer circuit 322, and a voltage generator 334 based on the received command CMD and/or column address Y-ADDR. For example, the control logic circuit 324 may output various control signals for programming data to the memory cell array 312, reading data stored in the memory cell array 312, or erasing data stored in the memory cell array 312.

As a specific example, the control logic circuit 324 may decode the received column address Y-ADDR to generate a mat address MAT-ADDR, and transfer the generated mat address MAT-ADDR to the page buffer circuit 322. As another specific example, a voltage control signal CTRL_vol for performing the program operation, the read operation, or the erase operation may be generated and transferred to the voltage generator 334.

The second die 320 may further include an input and output circuit 326 electrically connected to the page buffer circuit 322. For example, the input and output circuit 326 may be disposed in the second die 320 among the first to third dies 310 to 330. The input and output circuit 326 may receive data to be input to the selected memory cell of the memory cell array 312 from the outside (e.g., from the storage controller 200 of FIG. 1) during the program operation, and transmit data read from the selected memory cell to the outside during the read operation.

The second die 320 may further include the second die select unit 328. The second die select unit 328 may receive an address ADDR from the outside (e.g., from the storage controller 200 of FIG. 1). The second die select unit 328 may select the column address Y-ADDR from the received address ADDR and transfer the column address Y-ADDR to the control logic circuit 324 and/or the page buffer circuit 322.

The second die 320 may be provided in plural. For example, a plurality of second dies 320 each of which has a configuration of FIG. 3 are provided. The second die select unit 328 of each of the plurality of second dies 320 may activate at least corresponding one of the plurality of second dies 320 based on the received address ADDR. This will be described below in more detail in reference to FIGS. 9A to 10 and 12.

The third die 330 may include the voltage generator 334. The voltage generator 334 may generate a voltage for performing the program operation, the read operation, and the erase operation on the memory cell array 312 based on the voltage control signal CTRL_vol received from the control logic circuit 324. For example, the voltage generator 334 may generate various types of word line voltages (e.g., program voltage, pass voltage, read voltage, or read pass voltage) to be applied to the word lines, or a well voltage to be supplied to a bulk (e.g., well region) where a plurality of memory cells are formed. The generated voltage may be transferred to the row decoder 314. Additionally, the voltage generator 334 may generate various voltages for performing the program operation, the read operation, and the erase operation, and transfer the generated voltages to the page buffer circuit 322.

The third die 330 may further include an input and output interface 332 for communication with the outside of the non-volatile memory device. For example, the input and output interface 332 may be disposed in the third die 330 among the first to third dies 310 to 330. In an embodiment, the input and output interface 332 may be included in the second die 320 and the third die 330. For example, a part of the input and output interface 332 may be included in the third die 330, and the other part of the input and output interface 332 may be included in the second die 320. The non-volatile memory device 300 may transmit and receive various signals, addresses, and data to and from the outside through the input and output interface 332, and may receive voltages from the outside.

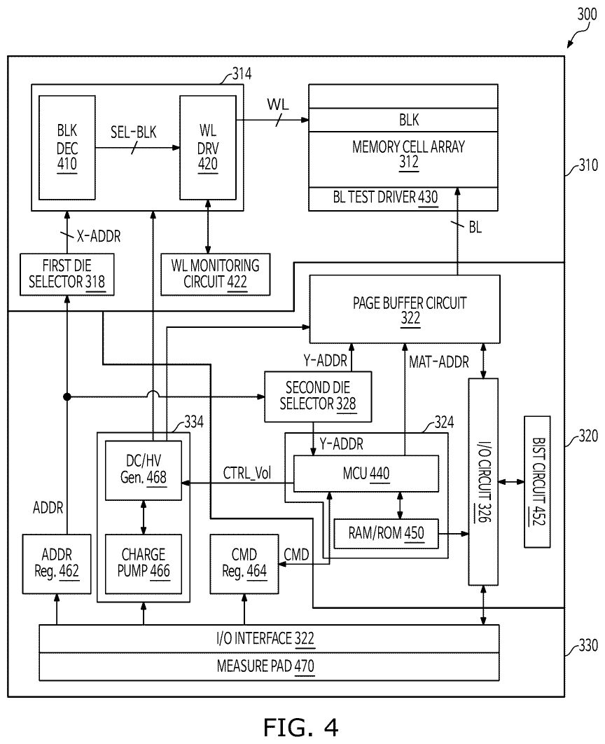

FIG. 4 is a diagram provided to explain an internal configuration of the non-volatile memory device 300. Hereinafter, the elements or operations already described above with reference to FIG. 3 will not be described or briefly described, and those added in FIG. 4 will be mainly described below.

Referring to FIG. 4, the first die 310 may include the memory cell array 312, the row decoder 314, and the first die select unit 318. The row decoder 314 may include a block decoder 410 and a word line driver 420.

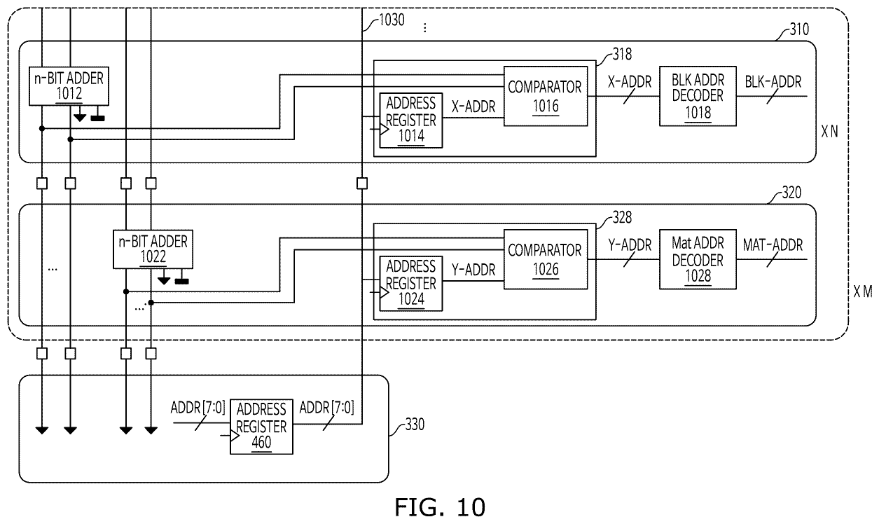

The block decoder 410 may generate a block select signal SEL-BLK, which is a signal for activating any one of the plurality of blocks, based on the row address X-ADDR and output the generated signal. For example, the row decoder 314 may include a block address decoder (not illustrated) that decodes the row address X-ADDR to generate and output a block address. In this case, the block decoder 410 may generate the block select signal SEL-BLK based on the block address output from the block address decoder and output the generated signal. The block address decoder will be described with reference to FIG. 10. In FIG. 10. the block address decoder is referenced with reference numeral 1018.

The word line driver 420 may transfer the word line voltage corresponding to the operation mode to the word lines of the activated block based on the row address X-ADDR and the control signal (not illustrated) received from the control logic.

The first die 310 may further include a word line monitoring circuit 422 and a bit line test driver 430 which are used for performing a test on the first die 310. Specifically, the word line monitoring circuit 422 may be electrically connected to the word line driver 420 and may be used for monitoring leakage current of the plurality of word lines WL. The bit line test driver 430 may be connected to the plurality of bit lines BL and may be used for performing a test (e.g., even/odd control) on the plurality of bit lines BL and the memory cell array 312.

The second die 320 may include the page buffer circuit 322, the control logic circuit 324, the input and output circuit 326, and the second die select unit 328. The control logic circuit 324 may include a micro controller unit (MCU) 440 and a RAM/ROM 450.

The MCU 440 may receive the command CMD and/or the column address Y-ADDR, and generate various control signals (e.g., the mat address MAT-ADDR, or the voltage control signal CTRL_Vol) for generally controlling the row decoder 314, the page buffer circuit 322, or the voltage generator 334 based on the received command CMD and/or column address Y-ADDR. A control logic (e.g., instructions or data) required for the MCU 440 to output various control signals may be stored in the RAM/ROM 450. The MCU 440 may generate various control signals by executing the control logic (e.g., instructions) stored in the RAM/ROM 450.

The second die 320 may further include a built-in self-test (BIST) circuit 452 used for performing a test on the second die 320. Specifically, the built-in self-test circuit 452 may be electrically connected to the input and output circuit 326 and used for performing an input and output test (e.g., a test to check whether a predetermined input and output speed is satisfied) on the input and output circuit 326.

The third die 330 may include the voltage generator 334 and the input and output interface 332. The voltage generator 334 may include a charge pump 466 and a direct current/high voltage (DC/HV) generator 468.

The charge pump 466 may perform charge pumping on an input voltage (e.g., power supply voltage V_{CC}) to generate a high voltage that is higher than the input voltage. The DC/HV generator 468 may generate various types of voltages (e.g., word line voltage or bit line voltage) for each operation mode based on the voltage control signal CTRL_Vol received from the MCU 440 using the high voltage generated by the charge pump 466. In an embodiment, the DC/HV generator 468 may receive a high voltage from the outside and generate various types of voltages using the high voltage provided from the outside.

The third die 330 may further include an address register 462 and/or a command register 464. The address ADDR received from the outside through the input and output interface 332 may be temporarily stored in the address register 462, and the address ADDR temporarily stored in the address register 462 may be transferred to the first die select unit 318 and/or the second die select unit 328. In addition, the command CMD received from the outside through the input and output interface 332 may be temporarily stored in the command register 464, and the command CMD temporarily stored in the command register 464 may be transferred to the control logic circuit 324.

The third die 330 may further include a measure pad 470. A test on the third die 330 and/or the non-volatile memory device 300 may be performed through the measure pad 470. For example, a test on electrical characteristics of the third die 330 (e.g., a test on a voltage level of the voltage generated by the DC/HV generator 468) may be performed through the measure pad 470.

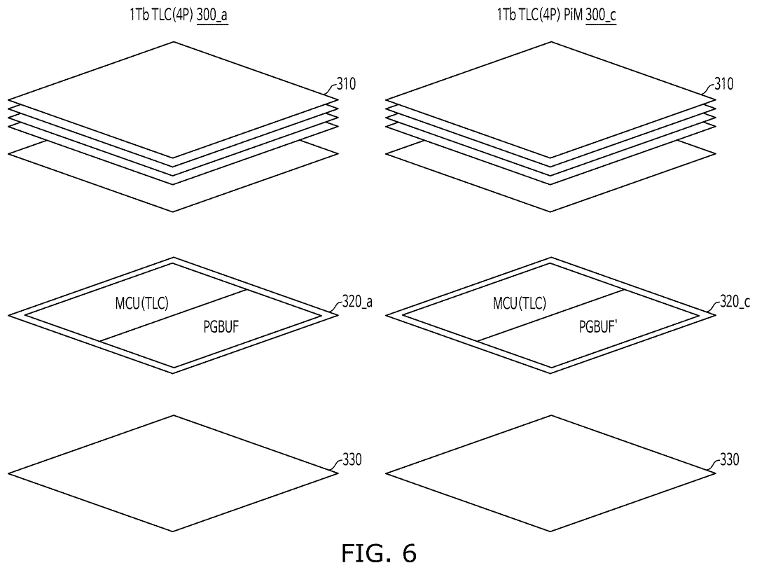

FIGS. 5 and 6 are diagrams provided to explain examples of non-volatile memory devices 300_a, 300_b, and 300_c combined according to some aspects. According to some aspects, various types of first dies 310, second dies 320_a, 320_b, and 320_c, and third die 330 may be combined with each other to manufacture various types of non-volatile memory devices 300_a, 300_b, and 300_c.

Referring to FIG. 5, the various types of non-volatile memory devices 300_a and 300_b may be manufactured according to the types of control logic circuits included in the second dies 320_a and 320_b. For example, the first die 310 including a specific number of memory cells, a first type of second die 320_a including a first type of control logic circuit (MCU (TLC)), and the third die 330 may be combined with each other to manufacture a first type of non-volatile memory device (1 Tb TLC 4P) 300_a having a triple-level cell (TLC) of a total capacity of 1Tb. The first type of control logic circuit (MCU (TLC)) may be a type of control logic circuit that controls each operation mode so that one memory cell stores 3 bits.

As another example, the first die 310 including a specific number of memory cells, a second type of second die 320_b including a second type of control logic circuit (MCU (QLC)), and the third die 330 may be combined with each other to manufacture a second type of non-volatile memory device (1.33 Tb QLC 4P) 300_b having a quad-level cell (QLC) of a total capacity of 1.33 Tb. The second type of control logic circuit (MCU (QLC)) may be a type of control logic circuit that controls each operation mode so that one memory cell stores 4 bits.

Referring to FIG. 6, the various types of non-volatile memory devices 300_a and 300_c may be manufactured according to the types of control logic circuits included in the second dies 320_a and 320_c. For example, the first die 310 including a specific number of memory cells, the first type of second die 320_a including the first type of control logic circuit ((MCU (TLC))) and a first type of page buffer circuit (PGBUF) which is a general page buffer, and the third die 330 may be combined with each other to manufacture the first type of non-volatile memory device 300_a.

As another example, the first die 310 including a specific number of memory cells, a third type of second die 320_c including the first type of control logic circuit (MCU (TLC)) and a second type of page buffer circuit PGBUF′, and the third die 330 may be combined with each other to manufacture a third type of non-volatile memory device (1Tb TLC (4P) PiM (Processing in Memory)) 300_c capable of performing a data operation. The second type of page buffer circuit PGBUF′ may be a page buffer with an added operation function. For example, the second type of page buffer PGBUF′ may include an operation unit for Multi-Accumulate (MAC) operation to enhance error correction by gathering information from multiple read operations, enabling more accurate data recovery, and extending the endurance of the non-volatile memory device 300_c. And for example, MAC operation of the operation unit of the page buffer PGBUF′ can also be utilized in AI models such as neural networks. For example, MAC operations are used in the process of multiplying each neuron's input by a weight and summing the results. This process is essential for the model to process data and learn the relationships between inputs and weights. For instance, in convolutional neural networks (CNNs) or fully-connected layers, each neuron computes its final output by multiplying input data by weights and accumulating the results. And for another example, the second type of page buffer PGBUF′ may include an operation unit for Multi-Accumulate (MAC) operation (e.g., operations that combine multiplication and addition and perform them repeatedly) to implement Processing-In-Memory (PIM) technology that performs data processing directly inside the non-volatile memory device 300_c. PIM technology can enable high-speed data computation, alleviate memory bandwidth bottlenecks by minimizing data movement, reduce power consumption, and enhance energy efficiency through optimized in-memory operations.

While FIGS. 5 and 6 show certain examples, they are for illustration purpose only, and the types of non-volatile memory devices that may be manufactured according to aspects of the present disclosure are not limited thereto. In addition to the examples described above, various types of the first die 310, second die 320, and third die 330 may be combined with each other to manufacture various types of non-volatile memory devices 300.

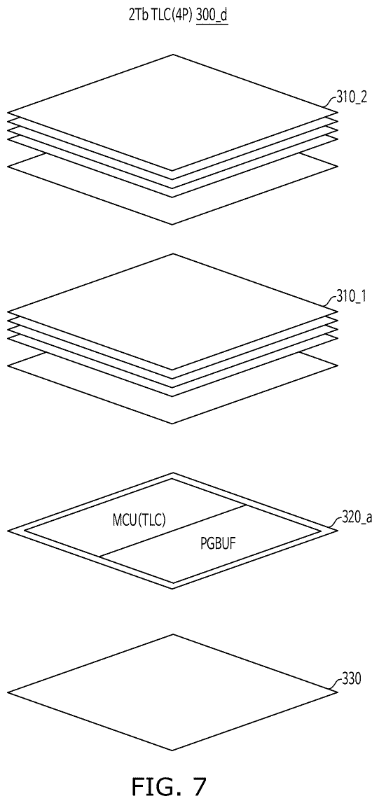

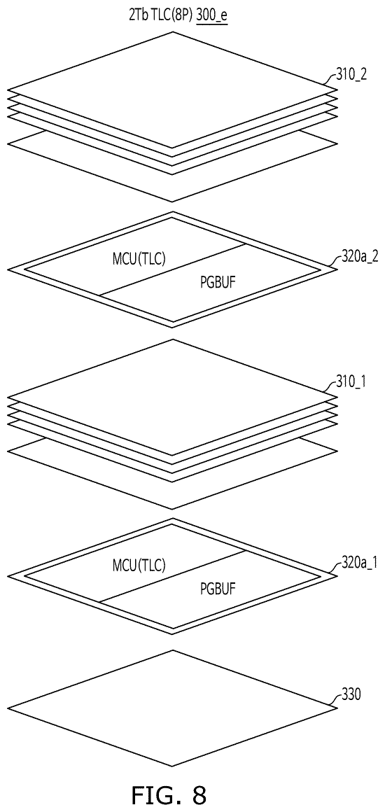

FIGS. 7 and 8 are diagrams provided to explain examples of non-volatile memory devices 300_d and 300_e stacked according to some aspects. According to some aspects of the present disclosure, the first die 310, the second die 320, and the third die 330 may be stacked in various ways to manufacture various types of non-volatile memory devices 300_d and 300_e.

Referring to FIG. 7, the non-volatile memory device 300_d may include a plurality of first dies 310_1 and 310_2. For example, a fourth type of non-volatile memory device (2 Tb TLC (4P)) 300_d may include a 1-1 die 310_1 including a first memory cell array including a specific number of memory cells and a first row decoder, and a 1-2 die 310_2 including a second memory cell array including a specific number of memory cells and a second row decoder. In addition, the fourth type of non-volatile memory device 300_d may have a stacked structure in which the third die 330, the second die 320_a, the 1-1 die 310_1, and the 1-2 die 310 2 are sequentially stacked on each other from one side to the other.

The page buffer circuit included in the second die 320_a may be electrically connected through a bit line to the first memory cell array included in the 1-1 die 310_1 and the second memory cell array included in the 1-2 die 310_2. In addition, the control logic circuit included in the second die 320_a may control the first row decoder included in the 1-1 die 310_1 and the second row decoder included in the 1-2 die 310 2. The first die select unit included in the 1-1 die 310_1 and the 1-2 die 310_2 may receive the address and activate any one of the plurality of first dies 310_1 and 310_2 based on the received address.

The fourth type of non-volatile memory device 300_d including two first dies 310_1 and 310_2 may have twice the capacity compared to the example including one first die (e.g., the first type of non-volatile memory device 300_a of FIGS. 5 and 6).

The example illustrated and described in FIG. 7 is for illustration purpose only, and aspects are not limited thereto. According to some aspects of the present disclosure, a non-volatile memory device including n first dies may be implemented, and a non-volatile memory device including the n first dies may have n-times the capacity compared to the example including one first die (e.g., the first type of non-volatile memory device 300_a of FIGS. 5 and 6). In an embodiment, “n” is an integer greater than 1.

Referring to FIG. 8, the non-volatile memory device 300_e may include a plurality of second dies 320a_1 and 320a_2. For example, a fifth type of non-volatile memory device (2 Tb TLC 8P) 300_e may include a 2-1 die 320a_1 including a first page buffer and a first control logic circuit, and a 2-2 die 320a_2 including a second page buffer and a second control logic circuit. In addition, the fifth type of non-volatile memory device 300_e may have a stacked structure in which the third die 330, the 2-1 die 320a_1, the 1-1 die 310_1, the 2-2 die 320a_2 and the 1-2 die 310_2 are sequentially stacked on each other from one side to the other.

The first page buffer circuit included in the 2-1 die 320a_1 may be electrically connected through first bit lines to the first memory cell array included in the 1-1 die 310_1 stacked on the 2-1 die 320a_1. In addition, the second page buffer circuit included in the 2-2 die 320a_2 may be electrically connected through second bit lines to the second memory cell array included in the 1-2 die 310_2 stacked on the 2-2 die 320a_2.

In addition, the first control logic circuit included in the 2-1 die 320a_1 may control the first row decoder included in the 1-1 die 310_1 stacked on the 2-1 die 320a_1. In addition, the second control logic circuit included in the 2-2 die 320a_2 may control the second row decoder included in the 1-2 die 310_2 stacked on the 2-2 die 320a_2.

The second die select units included in the 2-1 die 320a_1 and the 2-2 die 320a_2 may receive the address and activate at least one of the plurality of second dies 320a_1 and 320a_2 based on the received address. The plurality of second dies 320a_1 and 320a_2 included in the fifth type of non-volatile memory device 300_e may be activated at the same time to process data in parallel. For example, the fifth type of non-volatile memory device 300_e including two first dies 310_1 and 310_2 and two second dies 320a_1 and 320a_2 may have twice the capacity and twice the throughput compared to the example including one first die and one second die (e.g., the first type of non-volatile memory device 300_a of FIGS. 5 and 6).

The example illustrated and described in FIG. 8 is for illustration purpose only, and aspects are not limited thereto. According to some aspects of the present disclosure, a non-volatile memory device including n second dies may be implemented. A non-volatile memory device including n second dies may have n-times the throughput compared to the example including one second die (e.g., the first type of non-volatile memory device 300_a of FIGS. 5 and 6).

In addition, although it is illustrated in FIG. 8 that the first dies 310_1 and 310 2 are stacked one by one on each of the second dies 320a_1 and 320a_2, aspects are not limited thereto. According to another aspect, a non-volatile memory device having a plurality of first dies stacked on each of the second dies may be implemented. The same number of first dies may be stacked on each of the second dies, or different numbers of first dies may be stacked. For example, a non-volatile memory device including a stack of n sets of die sets may be implemented, in which the die set includes a second die and m first dies stacked on the second die. In an embodiment, “n” is an integer greater than 1, and “m” is an integer greater than 1. In this case, the non-volatile memory device may include n second dies and n×m first dies, and may have n-times the throughput and n×m times the capacity compared to the example including one first die and one second die (e.g., the first type of non-volatile memory device 300_a of FIGS. 5 and 6).

FIG. 9A is a diagram provided to explain a unique identifier generator. Referring to FIG. 9A, a non-volatile memory device may include a plurality of unique identifier generators. The plurality of unique identifier generators may assign different unique identifiers to each of the same type of dies (e.g., each of the plurality of first dies 310_1, 310_2, 310_3, and 310 4 and/or each of the plurality of second dies).

For example, the non-volatile memory device may include the plurality of first dies 310_1, 310_2, 310_3, and 310_4, and the plurality of first dies 310_1, 310_2, 310_3, and 310_4 may include a plurality of unique identifier generators that assign different unique identifiers to each of the plurality of first dies 310_1, 310_2, 310_3, and 310_4.

The plurality of unique identifier generators may include a plurality of n-bit adders 910_2, 910_3, and 910_4 electrically connected to each other. Each of the plurality of n-bit adders may output the unique identifier of the m-th first die plus a pre-designated number (e.g., 1) to generate a unique identifier of the m+1-th first die. For example, the n-bit adder may generate a maximum of 2″ unique identifiers of the first dies.

For example, a non-volatile memory device may include the 1-1 die 310_1, the 1-2 die 310_2, a 1-3 die 310_3, and a 1-4 die 310_4, as illustrated. The four first dies 310_1, 310_2, 310_3, and 310_4 may include a plurality of 2-bit adders 910_1, 910_2, 910_3, and 910_4 as the unique identifier generators. For example, the 1-1 die 310_1 may receive a ground voltage from the third die 330 as a starting unique identifier, and accordingly, the 1-1 die 310_1 may have a unique identifier “00₍₂₎”. A first 2-bit adder 910_1 included in the 1-1 die 310_1 may output the unique identifier of the 1-1 die 310_1 plus 1, so that a unique identifier of the 1-2 die 310_2 may be generated. Accordingly, the 1-2 die 310_2 may have a unique identifier “01₍₂₎”. In addition, the second 2-bit adder 910_2 included in the 1-2 die 310_2 may output the unique identifier of the 1-2 die 310_2 plus 1, so that a unique identifier of the 1-3 die 310_3 may be generated. Accordingly, the 1-3 die 310_3 may have a unique identifier “10₍₂₎”. In a similar manner, the 1-4 die 310_4 may have a unique identifier “11₍₂₎”. For example, different unique identifiers may be assigned to each of the four first dies 310_1, 310_2, 310_3, and 310_4 by the plurality of unique identifier generators included in the four first dies 310_1, 310_2, 310_3, and 310_4, that is, by the plurality of 2-bit adders 910_1, 910_2, 910_3, and 910_4.

In an embodiment, the non-volatile memory device may include a plurality of second dies, and the plurality of second dies may include unique identifier generators. In this case, in the same and similar manner as described above, different unique identifiers may be assigned to each of the plurality of second dies by the unique identifier generators included in the plurality of second dies. FIG. 9A illustrates that the 2-bit adder 910_1, 910_2, 910_3, and 910_4 included in each of the first dies 310_1, 310_2, 310_3, and 310_4 generates a unique identifier of the subsequent first die, but aspects are not limited thereto. For example, the 2-bit adder 910_1, 910_2, 910_3, and 910_4 included in each of the first dies 310_1, 310_2, 310_3, and 310_4 may generate its own unique identifier.

FIG. 9B is a diagram provided to explain a unique identifier generator. Referring to FIG. 9B, the non-volatile memory device may include the third die 330, a plurality of second dies 320_1 and 320_2 stacked on the third die 330, and a plurality of first dies 310_1, 310_2, 310_3, and 310_4, with one or more of the first dies 310_1, 310_2, 310_3, and 310_4 being stacked on each of the plurality of second dies 320_1 and 320_2. For example, the non-volatile memory device may have a stacked structure in which the third die 330, the 2-1 die 320_1, the 1-1 die 310_1, the 1-2 die 310_2, the 2-2 die 320_2, the 1-3 die 310_3, and the 1-4 die 310_4 are sequentially stacked on each other.

In the non-volatile memory device, the plurality of first dies 310_1, 310_2, 310_3, and 310_4 and the plurality of second dies 320_1 and 320_2 may include a plurality of unique identifier generators that assign different unique identifiers to each of the dies. For example, each of the plurality of first dies 310_1, 310_2, 310_3, and 310_4 and the plurality of second dies 320_1 and 320_2 may include an n-bit adder 920_1, 920_2, 920_3, 920_4, 930_1, and 930_2 as a unique identifier generator. The n-bit adders 920_1, 920_2, 920_3, 920_4, 930_1, and 930_2 included in each die may output an input plus a pre-designated number as a unique identifier of the corresponding die.

The first n-bit adder 920_1, 920_2, 920_3, and 920_4 included in each of the plurality of first dies 310_1, 310_2, 310_3, and 310_4 may be an adder that outputs an input plus a first pre-designated number (e.g., 1). In addition, the second n-bit adder 930_1 and 930_2 included in each of the plurality of second dies 320_1 and 320_2 may be an adder that outputs an input plus a second pre-designated number (e.g., 2ª (q is an integer greater than or equal to 0). The second pre-designated number may be greater than the first pre-designated number. Alternatively, the first pre-designated number (e.g., 24 (q is an integer greater than or equal to 0) may be greater than the second pre-designated number (e.g., 1).

If the second n-bit adder 930_1 and 930_2 included in each of the plurality of second dies 320_1 and 320_2 is an adder that outputs an input plus 24, q-th bit and bits lower than q-th bit of the unique identifiers may be used for identifying the row address in the plurality of first dies 310_1, 310_2, 310_3, and 310_4, and q+1-th bit and bits higher than q+1-th bit may be used for identifying the column address in the plurality of second dies 320_1 and 320 2.

For example, each of the plurality of first dies 310_1, 310_2, 310_3, and 310_4 may include the first n-bit adder 920_1, 920_2, 920_3, and 920_4 as a unique identifier generator that outputs an input plus 1, and each of the plurality of second dies 320_1 and 320_2 may include the second n-bit adder 930_1 and 930_2 as a unique identifier generator that outputs an input plus 2³. In this example, a second n-bit adder (2-1) 930_1 included in the 2-1 die 320_1 may receive a ground voltage as an input from the third die 330 and output the input plus 23, that is, “01000₍₂₎” as a unique identifier of the 2-1 die 320_1. The first n-bit adder (1-1) 920_1 included in the 1-1 die 310_1 may output the unique identifier of the 2-1 die 320_1 plus 1, that is, “01001₍₂₎” as the unique identifier of the 1-1 die 310_1. The first n-bit adder (1-2) 920_2 included in the 1-2 die 310_2 may output the unique identifier of the 1-1 die 310_1 plus 1, that is, “01010₍₂₎” as the unique identifier of the 1-2 die 310_2. In addition, the second n-bit adder (2-2) 930_2 included in the 2-2 die 320_2 may output the unique identifier of the 1-2 die 310_2 plus 23, that is, “10010₍₂₎” as a unique identifier of the 2-2 die 320 2.

In a similar manner, the 1-3 die 310_3 may have “10011₍₂₎” as a unique identifier, and the 1-4 die 310_4 may have “10100₍₂₎” as a unique identifier.

With this configuration, different unique identifiers may be assigned to each of the plurality of first dies 310_1, 310_2, 310_3, and 310_4 and the plurality of second dies 320_1 and 320_2 by the plurality of n-bit adders electrically connected to each other. In this example, the third bit and bits lower than the third bit of the unique identifiers (e.g., “001₍₂₎”, “010₍₂₎”, “011₍₂₎” and “100₍₂₎”, which are the first to third bits of the unique identifiers of the plurality of first dies 310_1, 310_2, 310_3, and 310_4) may be used to activate the plurality of first dies 310_1, 310_2, 310_3, and 310_4, and the fourth bit and bits higher than the fourth bit of the unique identifiers (e.g., ‘01₍₂₎’ and ‘10₍₂₎’, which are the fourth and fifth bits of the unique identifiers of the plurality of second dies 320_1 and 320_2) may be used to activate the plurality of second dies 320_1 and 320 2.

FIG. 10 is a diagram provided to explain the die select units 318 and 328. Referring to FIG. 10, the non-volatile memory device may include a plurality of first dies 310, a plurality of second dies 320, and the third die 330. For example, in the non-volatile memory device, M second dies 320 may be stacked on the third die 330, and one set of first dies 310 may be stacked on each of the M second dies 320. The one set of first dies 310 may include N first dies 310 (N≥1). In this case, the non-volatile memory device may include M second dies 320 and N×M first dies 310. The number of the first dies 310 included in one set of first dies 310 stacked on each of the plurality of second dies 320 may be the same as each other. In another aspect, different numbers of the first dies 310 may be stacked on each of the plurality of second dies 320.

Each of the plurality of first dies 310 may include a first unique identifier generator 1012, the first die select unit 318, and a block address decoder 1018. The block address decoder 1018 may be included in the row decoder. In another example, the block address decoder 1018 may be implemented as a separate configuration outside the row decoder.

A plurality of first unique identifier generators (e.g., a plurality of first n-bit adders 1012 electrically connected to each other) included in the plurality of first dies 310 may assign different unique identifiers to each of the plurality of first dies 310, as described above with reference to FIGS. 9A and 9B.

The plurality of first die select units 318 included in the plurality of first dies 310 may receive the address ADDR and activate at least one of the plurality of first dies 310 based on the received address ADDR. The one or more first die select units 318 included in the one or more first dies 310 included in the set may receive the address ADDR and activate any one of the one or more first dies 310 included in the one set based on the received address ADDR.

For example, in response to determining that the received address ADDR is associated with the unique identifier of a specific first die 310, a specific first die select unit 318 included in the specific first die 310 may transfer at least a part of the address ADDR, corresponding to the row address X-ADDR, to the row decoder (e.g., the block address decoder 1018) included in the specific first die 310. In addition, in response to determining that the received address ADDR is not associated with the unique identifier of the specific first die 310, the specific first die select unit 318 included in the specific first die 310 may not transfer the at least part of the address ADDR, corresponding to the row address X-ADDR, to the row decoder included in the specific first die 310.

For example, each of the plurality of first die select units 318 may include a first address register 1014 and a first comparator 1016. Each of the plurality of first address registers 1014 may receive the address ADDR, and select a row address X-ADDR from the received address ADDR.

Each of a plurality of first comparators 1016 may compare at least a part of the row address X-ADDR selected from the first address register 1014 with the unique identifier. Specifically, in response to determining that the row address X-ADDR is associated with the unique identifier of the specific first die 310, a specific first comparator 1016 included in a specific first die 310 may transfer the row address X-ADDR to the block address decoder 1018.

In response to determining that the row address X-ADDR is not associated with the unique identifier of the specific first die 310, the specific first comparator 1016 included in the specific first die 310 may not transfer the row address X-ADDR to the block address decoder 1018.

According to the process described above, based on the received address ADDR, only the block address decoder 1018 included in any one of the one or more first dies 310 included in one set may receive the row address X-ADDR. The block address decoder 1018 receiving the row address X-ADDR may decode the row address X-ADDR to generate a block address BLK-ADDR, and may transfer the generated block address BLK-ADDR to the block decoder 410 as shown in FIG. 4.

Each of the plurality of second dies 320 may include a second unique identifier generator 1022, the second die select unit 328, and a mat address decoder 1028. The mat address decoder 1028 may be included in the control logic and/or the page buffer circuit. In another example, the mat address decoder 1028 may be implemented as a separate configuration outside the control logic and/or page buffer circuit.

A plurality of second unique identifier generators (e.g., the plurality of second n-bit adders 1022 electrically connected to each other) included in the plurality of second dies 320 may assign different unique identifiers to each of the plurality of second dies 320 in a manner similar to that described above with reference to FIGS. 9A and 9B. Although FIG. 10 illustrates that the plurality of first unique identifier generators included in the plurality of first dies 310 and the plurality of second unique identifier generators included in the plurality of second dies 320 are not electrically connected to each other, aspects are not limited thereto. In another aspect, as described above with reference to FIG. 9B, the unique identifier generators included in the plurality of first dies 310 and the plurality of second dies 320 may be electrically connected to each other and assign different unique identifiers to each of the plurality of first dies 310 and the plurality of second dies 320.

The plurality of second die select units 328 included in the plurality of second dies 320 may receive the address ADDR and activate at least one of the plurality of second dies 320 based on the received address ADDR. For example, in response to determining that the received address ADDR is associated with a unique identifier of a specific second die 320, a specific second die select unit 328 included in the specific second die 320 may transfer at least a part of the address ADDR, corresponding to the column address Y-ADDR, to the control logic circuit and/or the page buffer circuit (e.g., the mat address decoder 1028 included in the control logic circuit and/or the page buffer circuit) included in the specific second die 320. In addition, in response to determining that the received address ADDR is not associated with the unique identifier of the specific second die 320, the specific second die select unit 328 included in the specific second die 320 may not transfer the at least the part of the address ADDR, corresponding to the column address Y-ADDR, to the control logic circuit and the page buffer circuit (e.g., the mat address decoder 1028 included in the control logic circuit and/or the page buffer circuit) included in the specific second die 320.

For example, each of the plurality of second die select units 328 may include a second address register 1024 and a second comparator 1026. Each of the plurality of second address registers 1024 may receive the address ADDR, select the column address Y-ADDR from the received address ADDR and output the same.

Each of the plurality of second comparators 1026 may compare at least a part of the column address Y-ADDR selected from the second address register 1024 with the unique identifier. Specifically, in response to determining that the column address Y-ADDR is associated with the unique identifier of a specific second die 320, a specific second comparator 1026 included in the specific second die 320 may transfer the column address Y-ADDR to the mat address decoder 1028. In response to determining that the column address Y-ADDR is not associated with the unique identifier of the specific second die 320, the specific second comparator 1026 included in the specific second die 320 may not transfer the column address Y-ADDR to the mat address decoder 1028.

According to the process described above, based on the received address ADDR, the mat address decoder 1028 included in at least one of the plurality of second dies 320 may receive the column address Y-ADDR. The mat address decoder 1028 receiving the column address Y-ADDR may decode the column address Y-ADDR to generate a mat address MAT-ADDR. At least some of the plurality of bit lines may be activated using the generated mat address MAT-ADDR. If the mat address decoders 1028 included in two or more of the plurality of second dies 320 receive the column address Y-ADDR, the two or more second dies may be activated at the same time to process data in parallel.

The plurality of first die select units 318 and the plurality of second die select units 328 may receive the address ADDR through a common address line 1030.

If the number (or length) of bits of the address ADDR is greater than the number (or length) of bits that can be transferred at a time through the common address line 1030 that transfers the address ADDR therethrough, the address ADDR may be transferred with a time division method. For example, if the length of the address ADDR exceeds a predetermined length, the address ADDR may be divided and transmitted in units of the predetermined length. As a specific example, if the number of bits that may be transferred at a time through the common address line 1030 is 8 bits and the address ADDR is more than 8 bits, the address ADDR may be transferred by 8 bits with a time division method. The transfer with time-division method may be performed by a storage controller connected to the non-volatile memory device, a control logic circuit of the non-volatile memory device, or a dedicated MCU. Although FIG. 10 illustrates that the number of bits that can be transmitted at a time through the common address line 1030 is 8 bits, this is only an example and aspects are not limited thereto.

In an embodiment, the plurality of first address registers 1014 and the plurality of second address registers 1024 may be electrically connected through the common address line 1030, and the address ADDR may be transferred to the plurality of first address registers 1014 and the plurality of second address registers 1024 through the common address line 1030. For example, the third die 330 may include a third address register 460 that may temporarily store the address ADDR received from the outside. The address ADDR may be transferred from the third address register 460 to the plurality of first address registers 1014 and the plurality of second address registers 1024 through the common address line 1030. The plurality of first address registers 1014 may select the row address X-ADDR from the address ADDR transferred through the common address line 1030. In addition, the plurality of second address registers 1024 may select the column address Y-ADDR from the address ADDR transferred through the common address line 1030. For example, each of the plurality of first address registers 1014 and the plurality of second address registers 1024 may receive a clock signal and output only an address ADDR corresponding to the received clock signal among the address ADDR received in a time-division method, allowing the selection of the row address X-ADDR or the column address Y-ADDR.

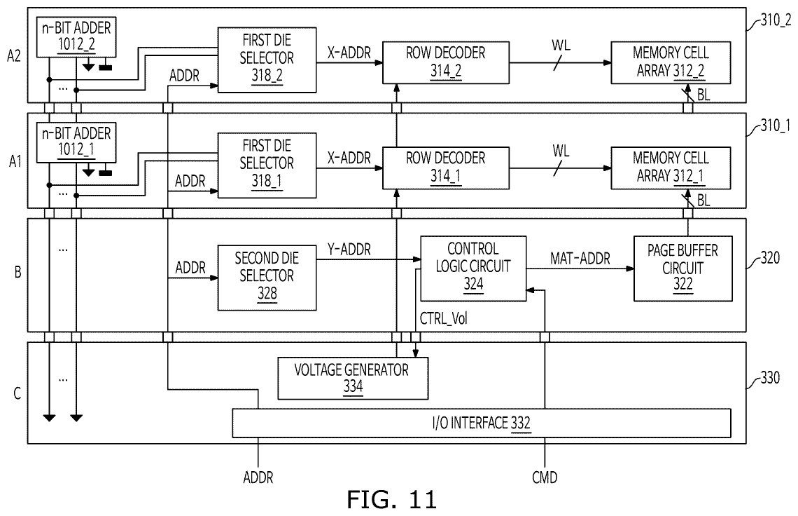

FIG. 11 is a block diagram illustrating an example of the non-volatile memory device 300 including the plurality of first dies 310_1 and 310_2. Referring to FIG. 11, the non-volatile memory device 300 may have a stacked structure in which the third die 330, the second die 320, and a plurality of first dies (e.g., the 1-1 die 310_1 and the 1-2 die 310_2) are sequentially stacked on each other from one side to the other.

Each of the plurality of first dies 310_1 and 310_2 may include a first unique identifier generator 1012_1 and 1012_2, a memory cell array 312_1 and 312_2, a row decoder 314_1 and 314_2, and a first die select unit 318_1 and 318_2. For example, the 1-1 die 310_1 may include a first memory cell array 312_1, a first row decoder 314_1, a first unique identifier generator 1012_1, and a 1-1 die select unit 318_1, and the 1-2 die 310_2 may include a second memory cell array 312 2, a second row decoder 314_2, a second unique identifier generator 1012_2, and a 1-2 die select unit 318 2.

At least one first unique identifier generator (e.g., the plurality of first n-bit adders 1012_1 and 1012_2 electrically connected to each other) included in the plurality of first dies 310_1 and 310_2 may assign different unique identifiers to each of the plurality of first dies 310_1 and 310_2.

The 1-1 die select unit 318_1 and the 1-2 die select unit 318_2 may receive the address ADDR, select the row address X-ADDR from the received address ADDR, and activate any one of the 1-1 die 310_1 and the 1-2 die 310 2 based on the row address X-ADDR. For example, if the row address X-ADDR is associated with the unique identifier of the 1-1 die 310_1, the 1-1 die select unit 318_1 may transfer the row address X-ADDR to the first row decoder 314_1 included in the 1-1 die 310_1, and the 1-2 die select unit 318_2 may not transfer the row address X-ADDR to the second row decoder 314 2 included in the 1-2 die 310_2. For example, if the row address X-ADDR is associated with the unique identifier of the 1-1 die 310_1, only the first row decoder 314_1 included in the 1-1 die 310_1 of the plurality of first dies 310_1 and 310 2 may receive the row address X-ADDR. In this case, the first row decoder 314_1 may select one block of the first memory cell array 312_1 based on the row address X-ADDR and activate word lines, of the plurality of word lines WL connected to the first memory cell array 312_1, which are included in the selected block.

The second die 320 may include the page buffer circuit 322, the control logic circuit 324, and the second die select unit 328. The second die select unit 328 may receive the address ADDR and select the column address Y-ADDR from the received address ADDR. In addition, the second die select unit 328 may transfer the column address Y-ADDR to the control logic circuit 324 and/or the page buffer circuit 322. For example, the second die select unit 328 may transfer the column address Y-ADDR to the control logic circuit 324. In this case, the control logic circuit 324 may decode the column address Y-ADDR to generate the mat address MAT-ADDR and transfer the generated mat address MAT-ADDR to the page buffer circuit 322. The page buffer circuit 322 may activate at least some of a plurality of bit lines BL connected to the memory cell arrays 312_1 and 312_2 based on the mat address MAT-ADDR.

The control logic circuit 324 included in the second die 320 may further receive a command CMD (e.g., a command indicating an operation mode) from the outside of the non-volatile memory device 300. The control logic circuit 324 may generate a voltage control signal CTRL_Vol based on the command CMD received from the outside and/or the column address Y-ADDR received from the second die select unit 328, and transfer the generated voltage control signal CTRL_vol to the voltage generator 334.

The third die 330 may include the input and output interface 332 and the voltage generator 334. The address ADDR and the command CMD may be received from the outside of the non-volatile memory device 300 through the input and output interface 332 included in the third die 330. In addition, the voltage generator 334 may generate a voltage based on the voltage control signal CTRL_vol and transfer the generated voltage to the first row decoder 314_1 of the activated 1-1 die 310_1. The voltage generator 334 may also transfer the generated voltage to the page buffer circuit 322 of the second die 320.

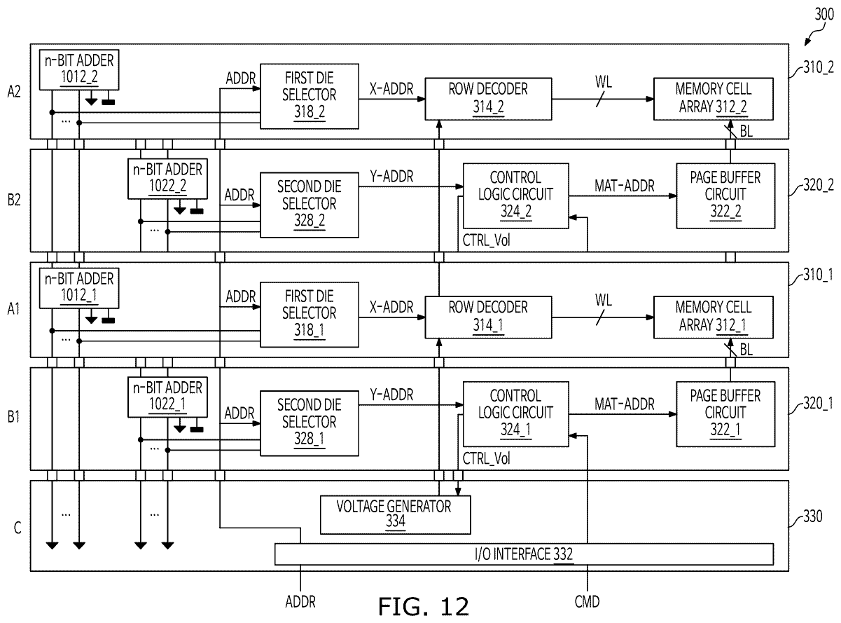

FIG. 12 is a block diagram illustrating an example of the non-volatile memory device 300 including the plurality of second dies 320_1 and 320_2. Referring to FIG. 12, the non-volatile memory device 300 may have a stacked structure in which the third die 330, the 2-1 die 320_1, the 1-1 die 310_1, the 2-2 die 320_2 and the 1-2 die 310_2 are sequentially stacked on each other from one side to the other side. Although FIG. 12 illustrates that the first dies 310_1 and 310_2 are stacked one by one on the second dies 320_1 and 320_2, this is only an example, and aspects are not limited thereto. In another example, one set of first dies including one or more first dies may be stacked on each of the second dies 320_1 and 320 2.

Each of the plurality of second dies 320_1 and 320_2 may include a second unique identifier generator 1022_1 and 1022_2, a page buffer circuit 322_1 and 322_2, a control logic circuit 324_1 and 324_2, and a second die select unit 328_1 and 328_2. For example, the 2-1 die 320_1 may include a second unique identifier generator 1022_1, a first page buffer circuit 322_1, a first control logic circuit 324_1, and a 2-1 die select unit 328_1, and the 2-2 die 320_2 may include a second unique identifier generator 1022_2, a second page buffer circuit 322_2, a second control logic circuit 324_2, and a 2-2 die select unit 328_2.

A plurality of second unique identifier generators (e.g., the plurality of second n-bit adders 1022_1 and 1022_2 electrically connected to each other) included in the plurality of second dies 320_1 and 320_2 may assign different unique identifiers to each of the plurality of second dies 320_1 and 320_2.

The 2-1 die select unit 328_1 and the 2-2 die select unit 328_2 may receive the address ADDR, select the column address Y-ADDR from the received address ADDR, and activate at least one of the 2-1 die 320_1 and the 2-2 die 320_2 based on the column address Y-ADDR.

For example, if the column address Y-ADDR is associated only with the unique identifier of the 2-1 die 320_1, the 2-1 die select unit 328_1 may transfer the column address Y-ADDR to the first control logic circuit 324_1 included in the 2-1 die 320_1, and the 2-2 die select unit 328_2 may not transfer the column address Y-ADDR to the second control logic circuit 324_2 included in the 2-2 die 320_2.

As another example, if the column address Y-ADDR is associated with the unique identifier of the 2-1 die 320_1 and the unique identifier of the 2-2 die 320_2, the 2-1 die select unit 328_1 and the 2-2 die select unit 328_2 may transfer at least a part of the column address Y-ADDR to the first control logic circuit 324_1 and the second control logic circuit 324_2, respectively. In this case, both the 2-1 die 320_1 and the 2-2 die 320_2 may be activated to process data in parallel. In some aspects, the second die select units 328_1 and 328_2 included in each of the second dies 320_1 and 320_2 may sequentially transfer the at least a part of the column address Y-ADDR to each of the control logic circuits 324_1 and 324_2. In this case, the 2-1 die 320_1 and the 2-2 die 320_2 may be sequentially activated.

Each of the at least one control logic circuit 324_1 and 324_2 receiving the column address Y-ADDR may decode the column address Y-ADDR to generate the mat address MAT-ADDR, and may transfer the generated mat address MAT-ADDR to the page buffer circuits 322_1 and 322_2. The page buffer circuits 322_1 and 322_2 may activate at least some of a plurality of bit lines BL connected to the memory cell arrays 312_1 and 312_2 based on the mat address MAT-ADDR.

For example, if only the first control logic circuit 324_1 of the plurality of control logic circuits 324_1 and 324_2 receives the column address Y-ADDR, the first control logic circuit 324_1 may decode the column address Y-ADDR to generate the mat address MAT-ADDR and transfer the generated mat address MAT-ADDR to the first page buffer circuit 322_1. The first page buffer circuit 322_1 may activate at least some of a plurality of bit lines BL connected to the first memory cell array 312_1 included in the 1-1 die 310_1 stacked on the 2-1 die 320_1 based on the mat address MAT-ADDR.

Each of the plurality of first dies 310_1 and 310_2 may include the first unique identifier generator 1012_1 and 1012_2, the memory cell array 312_1 and 312_2, the row decoder 314_1 and 314_2, and the first die select unit 318_1 and 318 2. In addition, the third die 330 may include the input and output interface 332 and the voltage generator 334. Most of the description of the plurality of first dies 310_1 and 310_2 and the third die 330 with reference to FIG. 11 may be similarly applied to the description of the non-volatile memory device 300 including the plurality of second dies 320_1 and 320_2 of FIG. 12. Hereinafter, only the differences of some aspects will be mainly described.

The 1-1 die select unit 318_1 and the 1-2 die select unit 318_2 may receive the address ADDR, select a row address X-ADDR from the received address ADDR, and activate at least some of the first dies (1-1) 310_1 and the first dies (1-2) 310_2 based on the row address X-ADDR.

In some aspects where only one first die 310_1 and 310_2 is stacked on each of the second dies 320_1 and 320_2, the first unique identifier generator and the first die select unit may not be substantially functional or may be omitted. For example, in some aspects where only one first dies 310_1 and 310_2 is stacked on each of the second dies 320_1 and 320_2, the first dies 310_1 and 310_2 stacked on at least some activated second dies 320_1 and 320_2 of the plurality of second dies 320_1 and 320_2 may be activated. As a specific example, if only the 2-1 die 320_1 of the plurality of second dies 320_1 and 320_2 is activated based on the column address Y-ADDR, only the 1-1 die 310_1 stacked on the 2-1 die 320_1 of the plurality of first dies 310_1 and 310_2 may be activated. As another specific example, if the 2-1 die 320_1 and the 2-2 die 320_2 are activated based on the column address Y-ADDR, the 1-1 die 310_1 stacked on the 2-1 die 320_1 and the 1-2 die 310_2 stacked on the 2-2 die 320_2 may be activated.

Alternatively, according to an aspect in which one set of first dies including a plurality of first dies are stacked on each of the second dies 320_1 and 320_2, as described above with reference to FIGS. 10 and 11, the plurality of first die select units 318_1 and 318 2 included in each set of first dies may receive the address ADDR, and activate any one of a plurality of first dies included in the one set based on the received address ADDR.

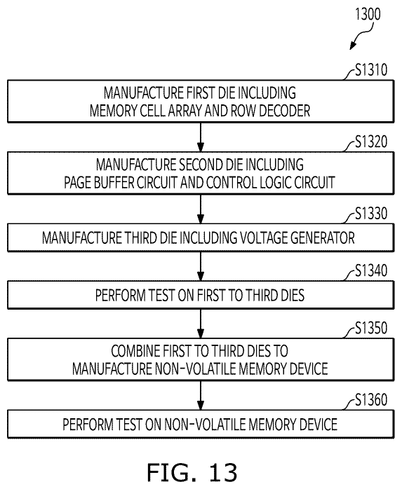

FIG. 13 is a flowchart illustrating an example of a method 1300 for manufacturing a non-volatile memory device. The method 1300 may be performed by a non-volatile memory manufacturing device and/or a test device.

At least one or more first dies each including a memory cell array including a plurality of blocks and a row decoder electrically connected to the memory cell array through a plurality of word lines may be manufactured at step S1310. For example, at least one first wafer including the first die including the memory cell array and the row decoder may be manufactured. The at least one first wafer may be diced to manufacture at least one or more first dies.

In addition, at least one or more second dies may be manufactured, each including the page buffer circuit electrically connected to the memory cell array through a plurality of bit lines, and the control logic circuit that controls the operation of the row decoder and the page buffer circuit at step S1320. For example, at least one second wafer including at least one or more second dies including the page buffer circuit and the control logic circuit may be manufactured. The at least one second wafer may be diced to manufacture at least one or more second dies.

The second die may further include the input and output circuit that transmits and receives data input to and read from the memory cell array. The input and output circuit may be electrically connected to the page buffer circuit.

In addition, the third die including the voltage generator that supplies a voltage to the page buffer circuit may be manufactured at step S1330. For example, a third wafer including the third die including the voltage generator may be manufactured. The third wafer may be diced to manufacture the third die.

A test may be performed on each of the at least one or more first dies, at least one or more second dies, and the third die at step S1340. For example, the first die may further include a word line monitoring circuit, and current leakage monitoring on the plurality of word lines may be performed using the word line monitoring circuit included in the first die. As another example, the first die may further include a bit line test driver, and a test on the plurality of bit lines and memory cell arrays may be performed using the bit line test driver included in the first die. As another example, the second die may further include a built-in self-test circuit, and an input and output test on the input and output circuit may be performed using the built-in self-test circuit included in the second die. As another example, the third die may further include a measure pad, and electrical characteristics of the third die may be measured using the measure pad included in the third die.

The at least one or more first dies, the at least one or more second dies, and the third die may be stacked on each other to manufacture a non-volatile memory device at step S1350. For example, the third die, the second die, and the first die may be sequentially stacked on each other from one side to the other to manufacture a non-volatile memory device. The at least one first wafer including the at least one or more first dies, the at least one second wafer including the at least one or more second dies, and the third wafer including the third die may be stacked on each other and bonded, and diced to manufacture a non-volatile memory device. In another example, the at least one or more first dies, the at least one or more second dies, and the third die, which are diced, may be stacked and bonded to manufacture a non-volatile memory device.

A non-volatile memory device including a plurality of first dies may be manufactured. For example, the third die, the second die, and a plurality of first dies may be sequentially stacked on each other from one side to the other to manufacture a non-volatile memory device.

In an embodiment, a non-volatile memory device including a plurality of second dies and a plurality of first dies may be manufactured. For example, the third die and a plurality of die sets may be sequentially stacked on each other from one side to the other to manufacture a non-volatile memory device. Each of the plurality of die sets may have a stacked structure in which the second die and one or more of the first dies are sequentially stacked.

A test on the manufactured non-volatile memory device may be performed at step S1360. For example, a test on the manufactured non-volatile memory device may be performed using the measure pad included in the third die.

The flowchart in FIG. 13 and the above description are merely examples, and it is to be noted that different implementations are possible in some other examples. For example, in some aspects, the order of the operations may be changed, some may be repeatedly performed, or some may be added, changed, and omitted.

1. A non-volatile memory device including a memory cell array, a row decoder, a page buffer circuit, a control logic circuit, and a voltage generator, comprising:
at least one first die including the memory cell array including a plurality of blocks and the row decoder electrically connected to the memory cell array through a plurality of word lines;
at least one second die including the page buffer circuit electrically connected to the memory cell array through a plurality of bit lines, and the control logic circuit configured to control an operation of the row decoder and the page buffer circuit; and
a third die including the voltage generator configured to supply voltage to the row decoder and the page buffer circuit, wherein the at least one first die, the at least one second die, and the third die are formed in a stacked structure.

2. The non-volatile memory device according to claim 1,
wherein the third die, the at least one second die, and the at least one first die are stacked in this order.

3. The non-volatile memory device according to claim 1,
wherein the at least one first die include, sequentially stacked on the at least one second die, a 1-1 die including a first memory cell array and a first row decoder, and a 1-2 die including a second memory cell array and a second row decoder,
wherein the 1-1 die includes a 1-1 die select circuit,
wherein the 1-2 die includes a 1-2 die select circuit, and
wherein the 1-1 die select circuit and the 1-2 die select circuit receive an address and activate one die among the at least one first die based on the address.

4. The non-volatile memory device according to claim 3,
wherein the at least one first die include a plurality of unique identifier generators that assign different unique identifiers to each of the at least one first die, and
wherein in response to the address being associated with a specific unique identifier associated with the 1-1 die, the 1-1 die select circuit transfers at least a part of the address to the first row decoder included in the 1-1 die with the 1-2 die select circuit not transferring the address to the second row decoder included in the 1-2 die.

5. The non-volatile memory device according to claim 4,
wherein the plurality of unique identifier generators include a plurality of n-bit adders, and
wherein the plurality of n-bit adders are electrically connected to each other.

6. The non-volatile memory device according to claim 4,
wherein the 1-1 die select circuit includes a comparator configured to compare at least part of the address with the specific unique identifier.

7. The non-volatile memory device according to claim 4,
wherein the first row decoder is configured to receive at least the part of the address and activates one of a plurality of blocks included in the first memory cell array and word lines associated with the one of the plurality of blocks included in the first memory cell array.

8. The non-volatile memory device according to claim 3,
wherein, when a length of the address exceeds a predetermined length, the address is divided and transmitted in units of the predetermined length, and
wherein each of the 1-1 die select circuit and the 1-2 die select circuit receives the address divided and transmitted in the units of the predetermined length.

9. The non-volatile memory device according to claim 1,
wherein the at least one second die include, stacked on the third die, a 2-1 die including a first page buffer circuit and a first control logic circuit, and a 2-2 die including a second page buffer circuit and a second control logic circuit,
wherein the 2-1 die includes a 2-1 die select circuit,
wherein the 2-2 die includes a 2-2 die select circuit, and
wherein the 2-1 die select circuit and the 2-2 die select circuit receive an address and activate at least one of the at least one second die based on the address.

10. The non-volatile memory device according to claim 9,
wherein the at least one second die include a plurality of unique identifier generators that assign different unique identifiers to each of the at least one second die, and
wherein in response to the address being associated with a specific unique identifier associated with the 2-1 die, the 2-1 die select circuit transfers at least a part of the address to at least one of the first control logic circuit and the first page buffer circuit included in the 2-1 die.

11. The non-volatile memory device according to claim 10,
wherein the first page buffer circuit is configured to select at least some of the plurality of bit lines connected to the memory cell array associated with the 2-1 die based on at least the part of the address.

12. The non-volatile memory device according to claim 9,
wherein the 2-1 die and the 2-2 die are activated at the same time to process data in parallel.

13. The non-volatile memory device according to claim 9,
wherein the at least one first die include a first set of first dies stacked on the 2-1 die and a second set of first dies stacked on the 2-2 die.

14. The non-volatile memory device according to claim 13,
wherein the first set of first dies includes a 1-1 die including a first memory cell array and a first row decoder, and a 1-2 die including a second memory cell array and a second row decoder,
wherein the 1-1 die includes a 1-1 die select circuit,
wherein the 1-2 die includes a 1-2 die select circuit, and
wherein the 1-1 die select circuit and the 1-2 die select circuit receive the address and activate one of the first set of first dies based on the address.

15. The non-volatile memory device according to claim 14,
wherein the 1-1 die select circuit, the 1-2 die select circuit, the 2-1 die select circuit, and the 2-2 die select circuit receive the address through a common address line.

16. The non-volatile memory device according to claim 13,
wherein each of the first set of first dies and the second set of first dies includes a first n-bit adder that outputs a value of an input plus a first pre-designated number,
wherein each of the 2-1 die and the 2-2 die includes a second n-bit adder that outputs a value of an input plus a second pre-designated number different from the first pre-designated number, and
wherein the first n-bit adder and the second n-bit adder are electrically connected to each other and assign different unique identifiers to the 2-1 die, the 2-2 die, each of the first set of first dies, and each of the second set of first dies.

17. The non-volatile memory device according to claim 1,
wherein the at least one second die further includes an input and output circuit electrically connected to the page buffer circuit, and configured to transmit and receive data input to and read from the memory cell array.

18. A non-volatile memory device including a plurality of memory cell arrays, a plurality of row decoders, a plurality of page buffer circuits, a plurality of control logic circuits, a plurality of input and output circuits, and a voltage generator, comprising:
a plurality of first dies each including a corresponding memory cell array, among the plurality of memory cell arrays, including a plurality of blocks, and a corresponding row decoder, among the plurality of row decoders, electrically connected to the corresponding memory cell array through a plurality of word lines;
a plurality of second dies each including a corresponding page buffer circuit, among the plurality of page buffer circuits, electrically connected to the corresponding memory cell array through a plurality of bit lines, a corresponding control logic circuit, among the plurality of control logic circuits, configured to control an operation of the corresponding row decoder and the corresponding page buffer circuit, and a corresponding input and output circuit, among the plurality of input and output circuits, electrically connected to the corresponding page buffer circuit and configured to transmit and receive data input to and read from the corresponding memory cell array; and
a third die including the voltage generator configured to supply a voltage to the corresponding row decoder and the corresponding page buffer circuit,
wherein the plurality of first dies, the plurality of second dies, and the third die are formed in a stacked structure,
wherein the plurality of first dies further include a first die select circuit that receives an address and activates at least one of the plurality of first dies based on the address, and
wherein the plurality of second dies further include a second die select circuit that receives the address and activates at least one of the plurality of second dies based on the address.

19. A method of manufacturing a non-volatile memory device including a memory cell array, a row decoder, a page buffer circuit, a control logic circuit, and a voltage generator, the method comprising:
manufacturing at least one first die including the memory cell array including a plurality of blocks, and the row decoder electrically connected to the memory cell array through a plurality of word lines;
manufacturing at least one second die including the page buffer circuit and the control logic circuit;
manufacturing a third die including the voltage generator;
performing a test on each of the at least one first die, the at least one second die, and the third die;
stacking the at least one first die, the at least one second die, and the third die to manufacture the non-volatile memory device, wherein in the non-volatile memory device, the page buffer circuit is electrically connected to the memory cell array through a plurality of bit lines, the control logic circuit is configured to control an operation of the row decoder and the page buffer circuit, and the voltage generator is configured to supply a voltage to the row decoder and the page buffer circuit; and
performing a test on the non-volatile memory device.

20. The method according to claim 19,
wherein the at least one second die further includes an input and output circuit electrically connected to the page buffer circuit and configured to transmit and receive data input to and read from the memory cell array, and
wherein the performing the test on each of the at least one first die, the at least one second die, and the third die includes:
performing current leakage monitoring on the plurality of word lines using a word line monitoring circuit included in the at least one first die;
performing a test on the plurality of bit lines and the memory cell array using a bit line test driver included in the at least one first die;
performing an input and output test on the input and output circuit using a built-in self-test (BIST) circuit included in the at least one second die; and
measuring electrical characteristics of the third die using a measure pad included in the third die.
